(19) United States
(12) Patent Application Publication
(10) Pub. No.: US 2018/0058778 A1
(43) Pub. Date: Mar. 1, 2018

(54) Heat Transfer Device and Method for Designing Heat Transfer Device

(71) Applicant: Mitsubishi Electric Research Laboratories, Inc., Cambridge, MA (US)

(72) Inventors: Bingnan Wang, Belmont, MA (US); Chungwei Lin, Boston, MA (US); Koon Hoo Teo, Lexington, MA (US); Yebin Wang, Cambridge, MA (US)

(21) Appl. No.: 15/245,666

(22) Filed: Aug. 24, 2016

(51) Int. Cl. F28F 13/14; H05K 7/20; F28F 27/00

(52) U.S. Cl. CPC F28F 13/14; F28F 2200/00; F28F 27/00; H05K 7/2039

(57) ABSTRACT

A heat transfer device includes a layered structure having a first layer of a first material having a first thermal conductivity and a first thickness and a second layer of a second material having a second thermal conductivity and a second thickness, the second layer being connected to the first layer. In the layered structure, the first thermal conductivity is different from the second thermal conductivity, and wherein the first thickness is different from the second thickness.

### FIELD OF THE INVENTION

This invention relates to a heat transfer device and a method for designing a heat transfer device, and more specifically, a heat transfer device having a predetermined temperature profile and a method for designing a heat transfer device with the predetermined temperature profile.

### BACKGROUND

A number of devices emit thermal energy in various quantities and forms. For example, electronic components, internal combustion engines, motors, electromechanical systems, and the like may emit thermal energy that is dissipated to the environment. The rapid dissipation of thermal energy from those heat sources, and an accurate control of the path of heat transfer are necessary for many of the applications, and have been considered under the scope of thermal management.

Thermal conductivity is a measure of how heat transfers through a material, and is generally intrinsically dependent on the particular material. A common practice for thermal management is to use materials with high thermal conductivity around the heat source, in order to rapidly dissipate the heat generated by the source, and avoid temperature accumulation. Such materials typically have isotropic thermal conductivity, which can result in non-linear temperature distribution of dissipated heat. However, the non-linear temperature distribution induces different amounts of thermal expansions through the material, resulting heat stress. There is need to reduce the heat stress by developing a structure of heat transfer materials.

### SUMMARY

Some embodiments of the invention are based on recognition that a non-linear temperature distribution through materials of a heat transfer device is advantageous for a number of thermal management applications, but in some cases can be suboptimal. For example, one embodiment is based on recognition that the non-linear temperature distribution of dissipated heat can cause the creation of undesirable hot spots in the heat transfer device. Another embodiment is based on recognition that the non-linear temperature distribution result in the large temperature gradient near heat source, which can cause material breakdown due to large thermal stress.

Additionally, or alternatively, some embodiments are based on recognition that some thermal management applications can benefit from propagation of the heat through the heat transfer device according to a predetermined profile of the temperature distribution approximating a function. For example, the knowledge of the function approximating the temperature distribution profile within a heat transfer device allows to better model and/or control a system that utilizes the heat transfer device. As used herein, a profile of the temperature distribution approximates a function when the function, such as a mathematical function, fits the data points of the temperature distribution within a predetermined margin of error.

For example, it is an object of one embodiment to provide a heat transfer device that the temperature distribution through materials of such a heat transfer device is linear. This embodiment is based on realization that if a heat in otherwise linear system is controlled according to a non-linear temperature distribution, the entire model of the system becomes non-linear. However, if the heat is controlled according to a linear temperature distribution, the entire system can be controlled using a linear model, which simplifies the structure of the controller.

Some embodiments are based on recognition that the predetermined profile of the temperature distribution can be achieved using composite materials of the heat transfer device. For example, a predetermined heat transfer can be designed using a layered structure of different materials having different thermal conductivity. The thermal conductivities of the materials are selected to enable the heat distribution according to the predetermined function.

However, to enable such a heat distribution, there is a need for specific relationship of thermal conductivities of the material forming each layer. It is not easy to find such a specific selection of the materials. For example, materials such as silver, copper, gold, aluminum, steel, and metal alloys can be used to form different layers of the heat transfer device. However, the difference between thermal conductivities of different pairs of materials is different, which complicates the design of the predetermined profile of the temperature distribution. In addition, some materials are more expensive than others and their use needs to be reduced. Accordingly, some embodiments are based on a realization that there is a need to design a heat transfer device with predetermined thermal conductivity temperature profile using a minimal number of different materials.

Some embodiments are based on realization that the thermal property of a material is not only a function of thermal conductivity of the material, but also a function of thickness of the layer of the material. To that end, by varying both the material and thickness of the layers, the requirement for the selection of the material can be reduced. For example, one embodiment uses only two different materials forming alternating layers, and the thickness of each layer is selected such that heat propagates through the heat transfer device according to an approximation of a function, e.g., a linear function.

Accordingly, one embodiment of the invention discloses a heat transfer device including a layered structure, which includes a first layer of a first material having a first thermal conductivity and a first thickness; and a second layer of a second material having a second thermal conductivity and a second thickness, the second layer being connected to the first layer, wherein the first thermal conductivity is different from the second thermal conductivity, and wherein the first thickness is different from the second thickness.

For example, the first thermal conductivity, the second thermal conductivity, the first thickness, and the second thickness are selected such that the heat propagates through the layered structure of the heat transfer device according to a temperature profile approximating a function. For example, the function is a linear function.

### BRIEF DESCRIPTION OF THE DRAWINGS

FIG. 1A is a schematic of a heat transfer device having a layered structure according to some embodiments of the invention;

FIG. 1B is a schematic of temperature propagation points for different layers of the heat transfer device according to some embodiments of the invention;

FIG. 1C is a schematic of selecting thermal conductivity of the layers as a function parameterized on the distance from the heat source;

FIG. 1D is a schematic of a monolayer structure of a cylindrical heat transfer device;

FIG. 1E is a schematic of a layered structure of a cylindrical heat transfer device;

FIG. 1F is a schematic of temperature simulation results of the cylindrical heat transfer devices solved under an identical boundary condition;

FIG. 2A is a schematic of a layered structure of an ellipse-shaped heat transfer device;

FIG. 2B, FIG. 2C and FIG. 2D are plots of simulation results of temperature profiles of ellipse-shaped heat transfer devices;

FIG. 3A is a schematic of a layered structure of a square-shaped heat transfer device formed of material layers with a square-shaped heat source;

FIG. 3B and FIG. 3C are plots of temperature profiles of the heat transfer device of FIG. 3A;

FIG. 4A is a schematic of a layered structure of a triangle-shaped heat transfer device formed of material layers;

FIG. 4B and FIG. 4C are plots of temperature profiles calculated for two directions;

FIG. 5A is a schematic of a layered structure of a cross-sectional view of a sphere-shaped heat transfer device;

FIG. 5B are plots of temperature profiles of a sphere-shaped heat transfer device;

FIG. 5C is a schematic of a layered structure of a cross-sectional view of a sphere-shaped heat transfer device;

FIG. 5D are plots of temperature profiles along the direction d;

FIG. 6 is a block diagram of a method for designing a heat transfer device providing a linear temperature profile;

FIG. 7A, FIG. 7B, FIG. 7C and FIG. 7D are schematics of a method for designing a heat transfer device according to some embodiments; and

FIG. 8 is a block diagram of a system including a heat source producing heat and the heat transfer device for dissipating the heat from the heat source that employs principles of some embodiments.

### DETAILED DESCRIPTION

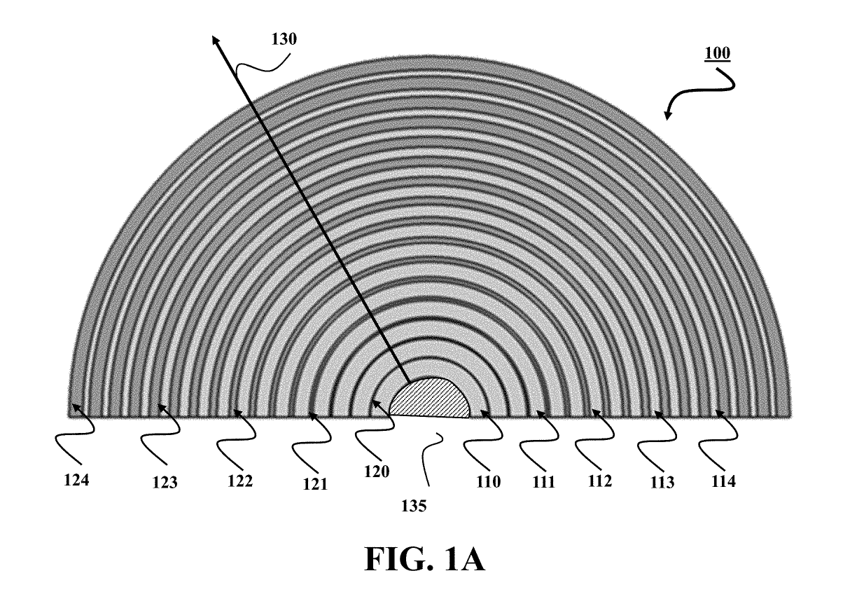

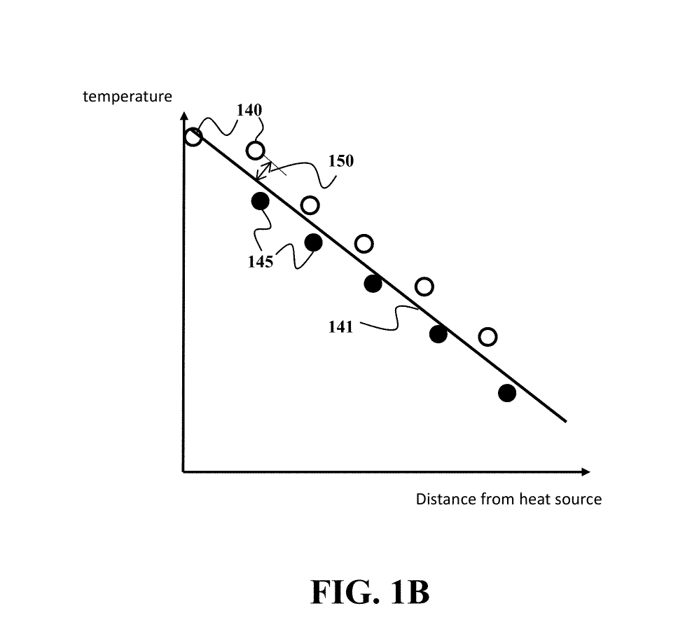

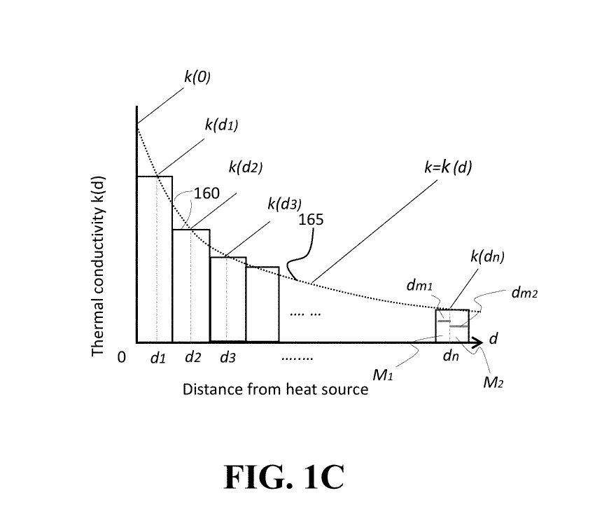

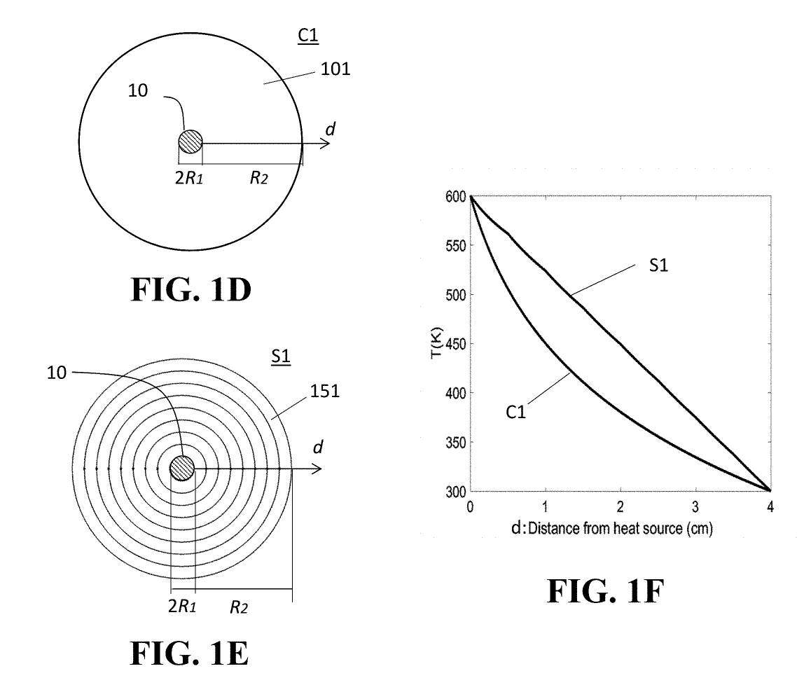

FIG. 1A shows a schematic of a heat transfer device 100 having a layered structure according to some embodiments of the invention. For example, the heat transfer device 100 includes a first layer 110 of a first material having a first thermal conductivity and a first thickness and a second layer 120 of a second material having a second thermal conductivity and a second thickness, the second layer being connected to the first layer. In various embodiments, the first thermal conductivity of the first material of the first layer 110 is different from the second thermal conductivity of the second material of the second layer 120. Also, the first thickness of the first layer 110 is different from the second thickness of the second layer 120.

Some embodiments are based on recognition that some thermal management applications can benefit from propagation of the heat through the heat transfer device according to a predetermined profile of the temperature distribution approximating a function. For example, the knowledge of the function approximating the temperature distribution profile within a heat transfer device allows to better model and/or control a system that generates heat dissipated using such a heat transfer device.

Some embodiments are based on recognition that the predetermined profile of the temperature distribution can be achieved using composite materials of the heat transfer device. To that end, heat transfer device 100 is designed using a layered structure of different materials having different thermal conductivity selected to enable the heat distribution according to the predetermined function. Specifically, the first thermal conductivity, the second thermal conductivity, the first thickness and the second thickness of the heat transfer device 100 are selected such that the heat propagates through the heat transfer device according to the thermal conductivity temperature profile approximating a function.

To enable such a heat distribution, there is a need for specific relationship of thermal conductivities of the material forming each layer. It can be difficult to find such a specific selection of the materials. For example, materials such as silver, copper, gold, aluminum, steel, and metal alloys can be used to form different layers of the heat transfer devise. However, the difference between thermal conductivities of different pairs of materials is different, which complicates the design of the predetermined profile of the temperature distribution. In addition, some materials are more expensive than others and their use needs to be reduced. Accordingly, some embodiments are based on a realization that there is a need to design a heat transfer device with predetermined thermal conductivity temperature profile using a minimal number of different materials.

Some embodiments are based on realization that the thermal property of a material is not only a function of thermal conductivity of the material, but also a function of thickness of the layer of the material. To that end, by varying both the material and thickness of the layers, the requirement for the selection of the material can be reduced. For example, one embodiment uses only two different materials forming alternating layers. However, alternative embodiments use different number of materials.

The thickness of each layer of material in the heat transfer device 100 is selected such that heat propagates through the heat transfer device according to an approximation of a function. As used herein, a profile of the temperature distribution approximates a function when the function, such as a mathematical function, fits the data points of the temperature distribution within a predetermined margin of error. In some embodiments, the function is a linear function. However different embodiments use different types of the function, e.g., polynomial functions and/or splines.

FIG. 1B shows a schematic of temperature propagation points corresponding to layers of the heat transfer device 100. Each circle 140 and/or 145 corresponds to a specific layer and represents temperature propagation points representing temperature propagation through the layer. For example, hollow circles 140 correspond to the layers made of the first material and filled circles 145 correspond to the layers made of the second material. The material and the thickness of the layers are selected such that the maximal error 150 between the temperature propagation points and the line 141 fitted into the points is below a threshold.

FIG. 1C shows a schematic of selecting thermal conductivity of layers as a function parameterized on the distance from the heat source. As a thermal conductivity profile 165 determines the temperature profile of a heat transfer device, a material needs to be selected to correspond to a predesigned thermal conductivity profile. In practical case, as it is not possible to realize a continuous thermal conductivity profile k(dₙ) by using a single layer of a single material, the thermal conductivity profile 165 is approximated by discretizing the thermal conductivity profile 165 with multiple regions 160. Each of the regions 160 is represented by a distance d from a heat source as shown in FIG. 1C. For instance, the region 160 at a distance d₁ has a thermal conductivity k(d₁), and the region 160 at a distance dₙ has a thermal conductivity k(dₙ). Discretization of the thermal conductivity profile 165 may be performed by a constant distance d as a unit distance.

The thermal conductivity k(dₙ) at a distance dₙ can be obtained as an effective thermal conductivity k_{meff} of a pair of first and second layered materials M₁ and M₂. When the first and second layered materials M₁ and M₂ respectively have first and second thicknesses dₘ₁ and dₘ₂ and first and second thermal conductivities kₘ₁ and kₘ₂, the effective thermal conductivity k_{meff} of the first and second materials M₁ and M₂ is expressed as follows.

$${k}_{meff} = \frac{{k}_{m 1} {k}_{m 2} ( {d}_{m 1} + {d}_{m 2} )}{{k}_{m 1} {d}_{m 2} + {k}_{m 2} {d}_{m 1}} \qquad ( 1 )$$

Accordingly, by choosing each pair of the first and second materials M₁ and M₂ and their thicknesses dₘ₁ and dₘ₂, a given thermal conductivity k(d) at a distance d (d>0) from the heat source can be approximated by the effective thermal conductivity k_{meff}. In other words, the thermal conductivity profile 165 can be approximated by combinations of pair of the first and second materials M₁ and M₂.

Parametrization on the distance from the heat source allows simplifying the design of the layers. For example, in an exemplar heat transfer device 100 the thicknesses of layers 111, 112, 113, and 114 of the first material in the alternating layers are decreasing as a function of a distance 130 from the heat source 135 and/or the second layer 120 arranged on the first layer. In contrast, thicknesses of layers 121, 122, 123, and 124 of the second material in the alternating layers are increasing as a function of the distance 130 from the heat source 135 and/or the second layer 120.

In some cases, the discretization of the thermal conductivity profile 165 may be performed by different unit distances. For instance, a distance dₙ may be smaller than dₙ₊₁ (n>0). This is effective when a temperature gradient near the heat source needs to be gentle compared to the other parts. It is also particularly effective to reduce a heat stress of the heat transfer device caused near the heat source due to a large amount of thermal expansion of the material of the heat transfer device.

Further, in some cases, a third material M3 or a fourth material M 4 may be added to the pair of the first and second materials to provide more flexibility for designing a thermal conductivity profile.

For example, it is an object of one embodiment to provide a heat transfer device that the temperature distribution through materials of such a heat transfer device is linear. This embodiment is based on realization that if a heat in otherwise linear system is controlled according to a non-linear temperature distribution, the entire model of the system becomes non-linear. However, if the heat is controlled according to a linear temperature distribution, the entire system can be controlled using a liner model, which simplifies the structure of the controller.

FIG. 1D and FIG. 1E show structures of cylindrical heat transfer devices C1 and S1. FIG. 1F shows temperature simulation results of the cylindrical heat transfer devices C1 and S1 solved under an identical boundary condition, respectively.

FIG. 1D indicates a cross section of the cylindrical heat transfer device C1 having a monolayer structure, in which a heat source 10 having a diameter 2R1 is arranged to fill the inner diameter 2R₁ of the cylindrical heat transfer device C1 and generates isotropic heat flux in all directions in two dimensions, i.e. no heat flowing in angular directions. The cylindrical heat transfer device C1 is made of a material 101 with a thickness R₂. It is assumed that the inner surface of the cylindrical heat transfer device C1 contacts the heat source 10 at a constant temperature T₁ and the outer surface of the heat transfer device C1 is maintained to be T₂ at a distance R₂ from the inner surface of the cylindrical heat transfer device C1 by a cooling system. It is also assumed that the heat flows only in all radial directions from the center of the heat source 10 to the outer surface of the cylindrical heat transfer device C1 through the material 101. For example, a thermal conductivity k of the material 100 distributes uniformly in the material 101.

In the steady-state, the heat equation of the cylindrical heat transfer device C1 is written by

$$\frac{d}{dr} ( kr \frac{dT}{dr} ) = 0. \qquad ( 2 )$$

Assuming that the steady state heat flux is q₁ (>0) at r=R₁, and parameters and boundary conditions are given by R₁<r<R₂, T₁>T₂, T(R₁)=T₁, and T(R₂)=T₂, a temperature profile T(r) in the cylindrical heat transfer device C1 is obtained by

$$T ( r ) = \frac{{q}_{1} {R}_{1}}{k} ln ( \frac{{R}_{2}}{r} ) + {T}_{2} . \qquad ( 3 )$$

### Further,

$${T}_{1} = \frac{{q}_{1} {R}_{1}}{k} ln ( \frac{{R}_{2}}{{R}_{1}} ) + {T}_{2} . \qquad ( 4 )$$

### Thus,

$$T ( r ) = \frac{{T}_{1} - {T}_{2}}{ln ( {R}_{2} / {R}_{1} )} ln ( \frac{{R}_{2}}{r} ) + {T}_{2} . \qquad ( 5 )$$

FIG. 1F shows a temperature profile of the cylindrical heat transfer device C1, indicating the temperature profile T(r) as a function of the distance r from the inner surface of the cylindrical heat transfer device C1 to the outer surface of the cylindrical heat transfer device C1. The temperature T(r) decreases as a function of the inverse of the distance from the interface of the heat source 10 and the material 101 according to equations (3) and (5). In this case, the boundary conditions are determined as an example case; R₁=0.5 cm R₂=4 cm, T₁=600° C., T₂=300° C. and k=60 W/m·K. However, the boundary conditions and the thermal conductivity can vary for different applications.

In order to obtain a linear temperature profile with respect to a cylindrical heat transfer device, a thermal conductivity profile k(r) across a cylindrical structure needs to satisfy a linear temperature profile requirement condition given by

$$k ( r ) = \frac{R}{r} k , \qquad ( 6 )$$

where R(=(R₁+R₂)/2) is an average radius of the cylindrical heat transfer device and k is a thermal conductivity of a predetermined material in the cylindrical heat transfer device of FIG. 1D.

FIG. 1E shows a layered structure of a cylindrical heat transfer device S1 including material layers 151. Each of the material layers 151 is arranged to satisfy the linear temperature profile requirement of equation (6), and an identical heat source 10 is arranged in the center of the cylindrical shell heat transfer device S1. The boundary conditions used are identical to those used in the calculation of the profile C1 except for the thermal conductivity profile k(r).

FIG. 1F shows a temperature profile S1 of the cylindrical heat transfer device S1 calculated under the linear temperature profile requirement of equation (6). It shows that the temperature profile S1 indicates a substantially linear line as discussed above. In the calculation, each of thermal conductivities of the layers 151 are chosen to satisfy the thermal conductivity profile k(r) of equation (6).

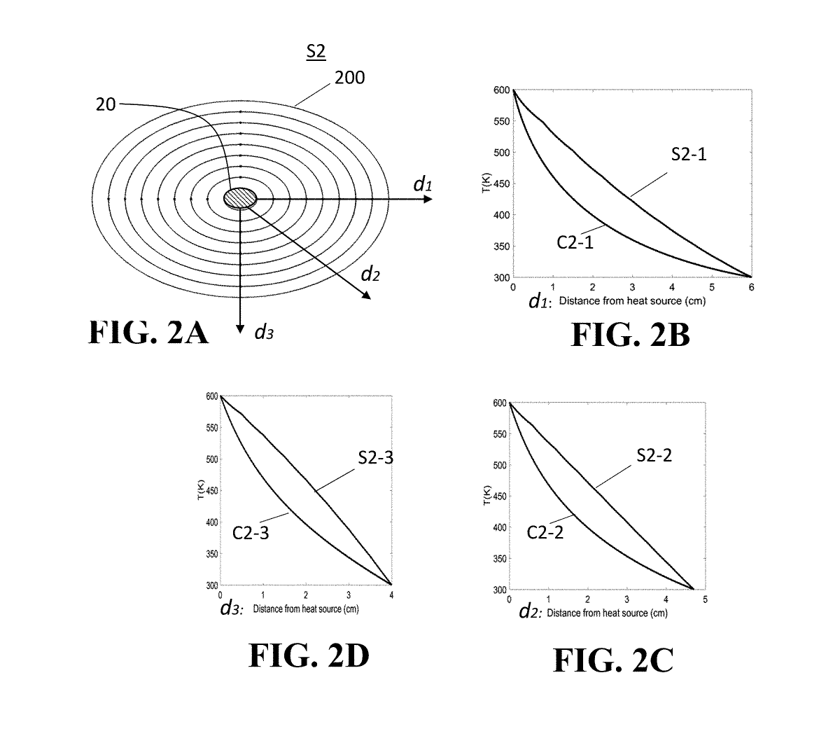

FIG. 2A shows an ellipse-shaped heat transfer device S2 including material layers 200. FIG. 2B, FIG. 2C and FIG. 2D show simulation results of temperature profiles with respect to the ellipse-shaped heat transfer device S2. For example, an ellipse-shaped heat source 20 can have a long radius of 1 cm and a short radius 0.5 cm and is arranged to contact the inner surface of the ellipse-shaped heat transfer device S2 and the heat flux qt flows uniformly across each of the material layers 200.

In the simulation, the temperature profiles are calculated for three directions d₁, d₂ and d₃, which are shown in FIG. 2B, FIG. 2C and FIG. 2D, respectively. As shown in the figures, the direction d₁ corresponds to a direction along the long radius of the ellipse, the direction d₃ corresponds to a direction along the short radius of the ellipse, and the direction d₂ corresponds to a direction having an angle between the d₁ and d₃ directions.

The thermal conductivity profile k(r) of the ellipse-shaped heat transfer device 200 is designed to satisfy equation (6) along the d₁ direction as a function of distance from the inner surface of the ellipse-shaped heat transfer device 200. In FIG. 2B, a temperature profile S2-1 shows an approximately linear profile as designed. It is noted that the temperature profiles S2-2 and S2-3 are also approximately straight lines. This indicates that the linear temperature profile requirement of equation (6) with respect to a cylindrical heat transfer structure is effective for an ellipse shaped heart transfer structure having a flatness rate similar to that indicated in FIG. 2A.

The temperature profiles C2-1, C2-2 and C2-3 in FIGS. 2B, 2C and 2D, indicating non-linear temperature profiles, are calculated by assuming that a thermal conductivity of each of the material layers 200 is a constant value identical to the thermal conductivity of the material 101 in FIG. 1D.

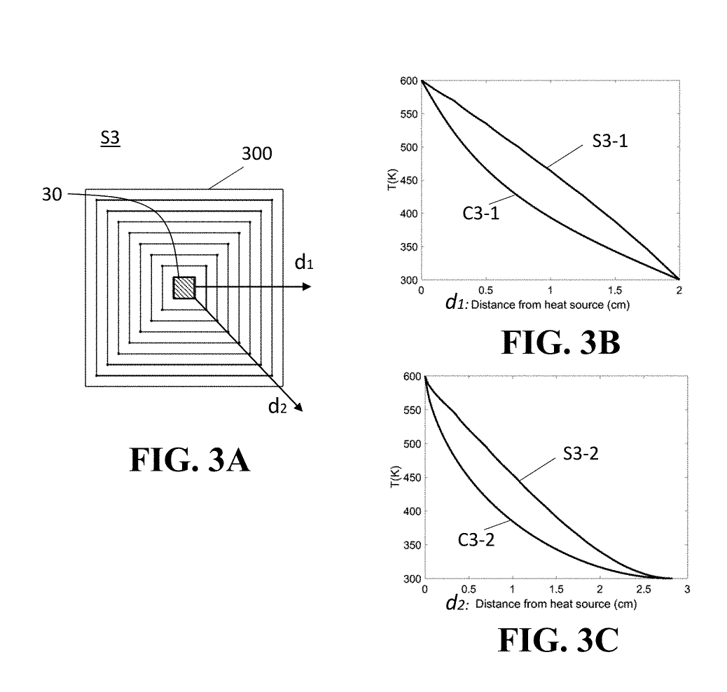

FIG. 3A shows a square-shaped heat transfer device S3 formed of material layers 300 with a square-shaped heat source 30 surrounded by the inner surface of the material layers 300. In this case, the heat equation is solved along directions d₁ and d₂.

FIG. 3B and FIG. 3C show temperature profiles S3-1, S3-2, C3-1 and C3-2 calculated for the directions d₁ and d₂. The temperature profile S3-1 shows approximately linear profile as a function of a distance from the inner surface to the outer surface along the direction d₁. The temperature profile S3-2 indicates approximately straight line up to 2 cm from the inner surface. This indicates that the linear temperature profile requirement of equation (6) can be applied to most regions of the square-shaped heat transfer device S3. Profiles C3-1 and C3-2 in FIGS. 3B and 3C can be obtained based on an assumption that the material layers 300 are replaced with the material 101 in FIG. 1D. The profiles C3-1 and C3-2 show that the temperatures drop abruptly with the distance from the heat source 30.

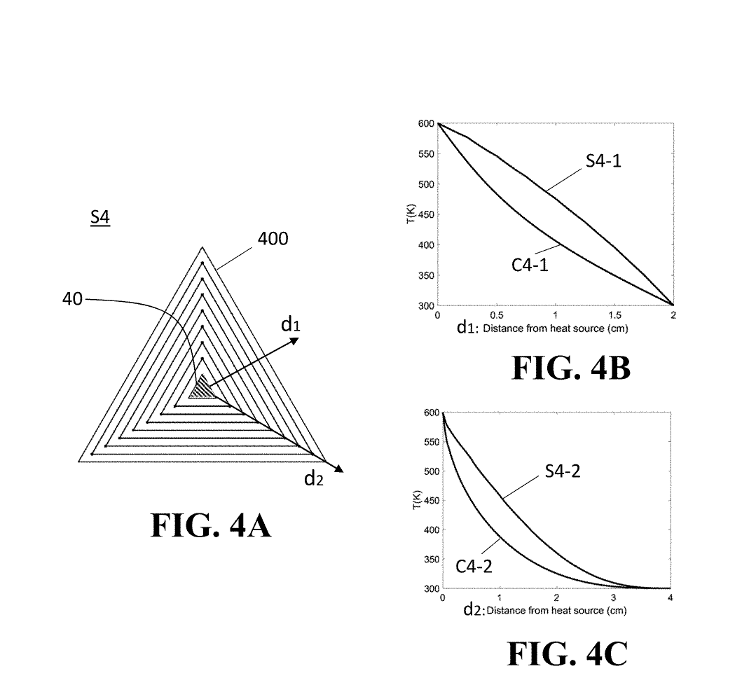

FIG. 4A shows a triangle-shaped heat transfer device S4 formed of material layers 400 with a triangle-shaped heat source 40 surrounded by the inner surface of the material layers 400. In this case, the heat equation is solved along directions d₁ and d₂ as indicated in the figure.

FIG. 4B and FIG. 4C show temperature profiles S4-1, S4-2, C4-1 and C4-2 calculated for the directions d₁ and d₂. The temperature profiles S4-1 and S4-2 are calculated under the boundary conditions equivalent to those used in the cylindrical heat transfer device S1 having material layers 150 shown in FIG. 1E. The C4-1 and C4-2 are calculated based on an assumption that the material layers 400 are replaced with the material 101 in FIG. 1D. In other words, the thermal conductivity k used to calculate temperature C4-1 and C4-2 is assumed to be a constant and uniformly distributed in all directions of the triangle-shaped heat source.

The temperature profiles S4-1 and C4-1 show approximately linear profiles as a function of the distance from the inner surface to the outer surface along the direction d₁ which corresponds to a vertical direction to the material layers 400. In the direction d₂, the profile S4-2 shows approximately linear distance dependency up to about 2.5 cm and gradually starts showing non-linearity as increase in the distance d₂. On the other hand, the profile C4-2 shows non-linearity in the whole region along the direction d₂.

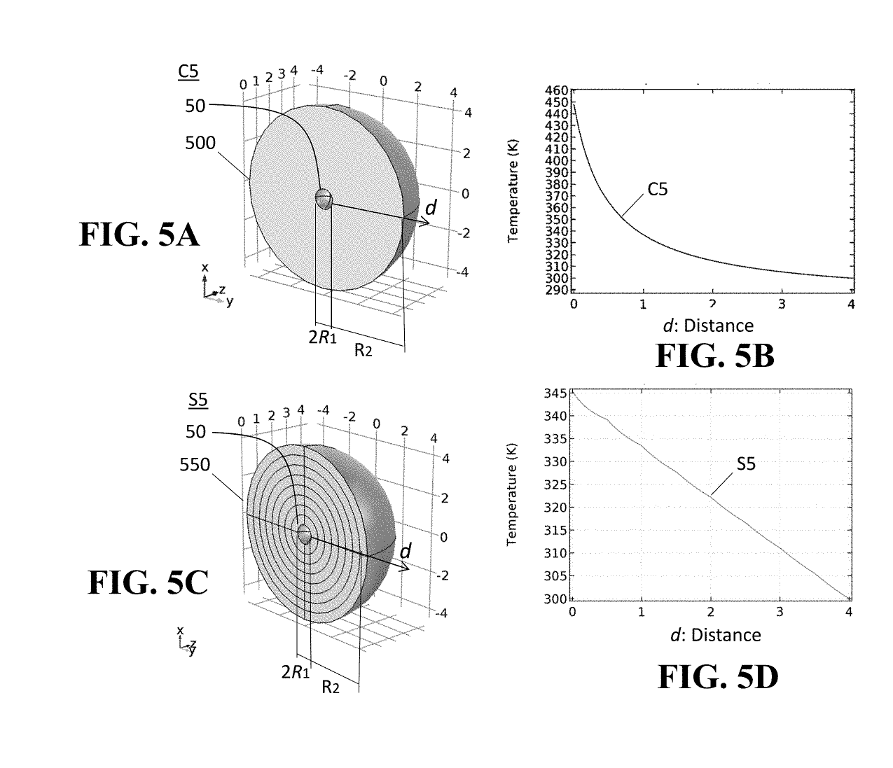

FIG. 5A shows a cross-sectional view of a sphere-shaped heat transfer device C5. The sphere-shaped heat transfer devices C5 is formed of a single material layer 500 with a spherical heat source 50 having a diameter 2R1 surrounded by the inner surface of the layer 500.

For the sphere-shaped heat transfer devices C5, the steady state heat equation with azimuthal and poloidal symmetry is simplified as

$$\frac{d}{dr} ( k ( r ) {r}^{2} \frac{dT}{dr} ) = 0. \qquad ( 7 )$$

As the thermal conductivity is assumed to uniformly distribute in all direction along the radius of the sphere, the temperature distribution across the sphere-shaped heat transfer devices C5 is written as

$$T ( r ) = \frac{{q}_{1} {R}_{1}^{2}}{k} ( \frac{1}{r} - \frac{1}{{R}_{2}} ) + {T}_{2} . \qquad ( 8 )$$

By assuming that the temperature at the interface of the spherical heat source 50 and the inner surface of the sphere-shaped heat transfer device C5 is constant at T₁, T(r) is given as

$$T ( r ) = \frac{{T}_{1} - {T}_{2}}{1 \text{/} {R}_{1} - 1 \text{/} {R}_{2}} ( \frac{1}{r} - \frac{1}{{R}_{2}} ) + {T}_{2} . \qquad ( 9 )$$

Equations (8) and (9) indicate the non-linearity of a temperature profile across the sphere-shaped heat transfer device C5.

FIG. 5B shows a temperature profile C5 of the sphere-shaped heat transfer device C5 calculated based on the conditions; a heat flux q₁=2×10⁶ W/m²,

a controlled temperature T(R₂)=T₂=300K at r=R₂, and thermal conductivity k=60 W/m·K. The temperature decreases with increase in the distance from the interface of the spherical heat source 50 and the material layer 500.

For a sphere-shaped heat transfer device S5, the linear temperature profile requirement condition is obtained by solving the heat equation (7) under a condition of ∂T/∂r=constant, as follows.

$$k ( r ) = \frac{( {R}_{1}^{2} + {R}_{1} {R}_{2} + {R}_{2}^{2} )}{3 {r}^{2}} k \qquad ( 10 )$$

When the thermal conductivity profile of the material layers 550 is designed to satisfy equation (10), the temperature profile T(r) across the heat transfer device S5 is expressed by

$$T ( r ) = \frac{3 {R}_{1}^{2} {q}_{1} ( {R}_{2} - r )}{( {R}_{1}^{2} + {R}_{1} {R}_{2} + {R}_{2}^{2} ) k} + {T}_{2} . \qquad ( 11 )$$

This provides the linearity of a temperature profile across a sphere-shaped heat transfer structure.

FIG. 5C shows a cross-sectional view of a sphere-shaped heat transfer device S5. The sphere-shaped heat transfer devices S5 is formed of material layer 550 with the spherical heat source 50 having a diameter 2R1 surrounded by the inner surface of the material layers 550.

FIG. 5D shows a temperature profile S5 along the direction d indicated in FIG. 5C. The temperature profile S5 indicates that the temperature linearly decreases as a function of the distance from the interface of the spherical heat source 50 and the inner surface of the material layers 550. Boundary conditions used in the present calculation are identical to those used in calculating the temperature profile C5, and individual layers of the material layers 550 are configured to have thermal conductivities that satisfy the linear temperature profile condition required by equation (10).

Design of Thermal Conductivity Profile of Heat Transfer Device

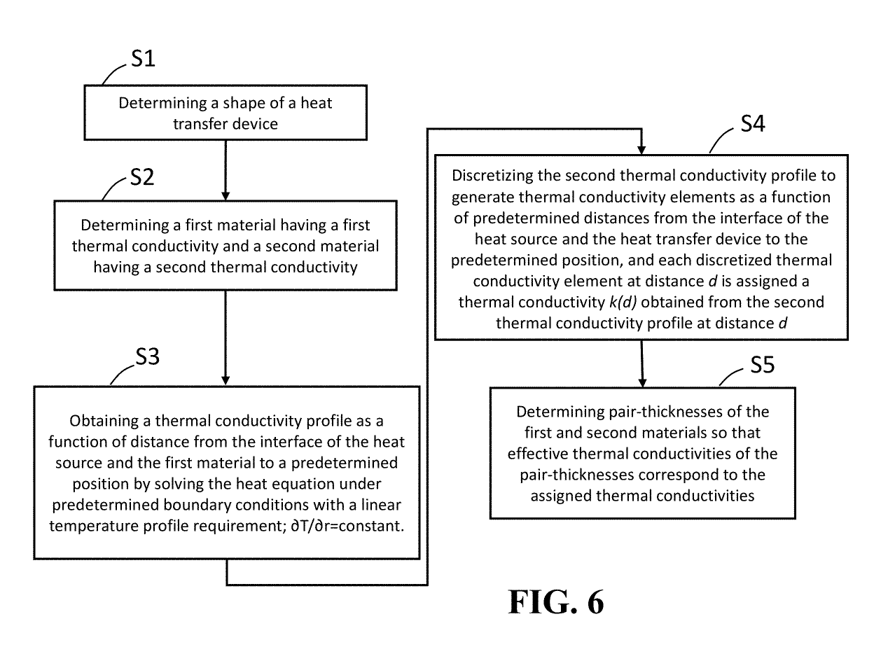

FIG. 6 shows a block diagram of a method for designing a heat transfer device that provides a linear temperature profile between different temperatures of materials, apparatuses or heat systems. In step S1, a shape of a heat transfer device is determined according to a predetermined system design. In step S2, a first material having a first thermal conductivity and a second material having a second thermal conductivity are selected from predetermined candidate heat transfer materials. Examples of materials include, but not limited to silver, copper, gold, aluminum, steel, and metal alloys can be used to form different layers of the heat transfer device.

The specific difference between thermal conductivities of different pairs of materials provides a flexibility of designing a heat transfer device. For instance, the thermal conductivities of candidate materials are: Silver (429 W/m·K); Copper (395 W/m·K); Gold (318 W/m·K); Aluminum (237 W/m·K); Brass (109 W/m·K); Stainless Steel (24 W/m·K); SUS410 (14.4 W/m·K), SUS304 (16.224 W/m·K); Metal alloys can have different values of thermal conductivity (e.g. Aluminum-Magnesium alloy have thermal conductivity values between 56 W/m·K and 135 W/m·K depending on the percentage of Magnesium).

Step S3 obtains a thermal conductivity profile as a function of distance from the interface of the heat source and the first material to a predetermined position by solving the heat equation under predetermined boundary conditions with a linear temperature profile requirement; ∂T/∂r=constant (r: heat conducting direction). In this case, the predetermined position may be defined as a predetermined temperature position in the heat transfer device.

In step S4, the thermal conductivity profile is discretized to generate thermal conductivity elements (layers) as a function of predetermined distances from the interface of the heat source and the heat transfer device (first material) to the predetermined position. In this case, each discretized thermal conductivity element at distance d is assigned a thermal conductivity k(d) obtained from the thermal conductivity profile at distance d.

Step S5 determines pair-thicknesses of the first and second materials so that effective thermal conductivities of the pair-thicknesses correspond to the assigned thermal conductivities.

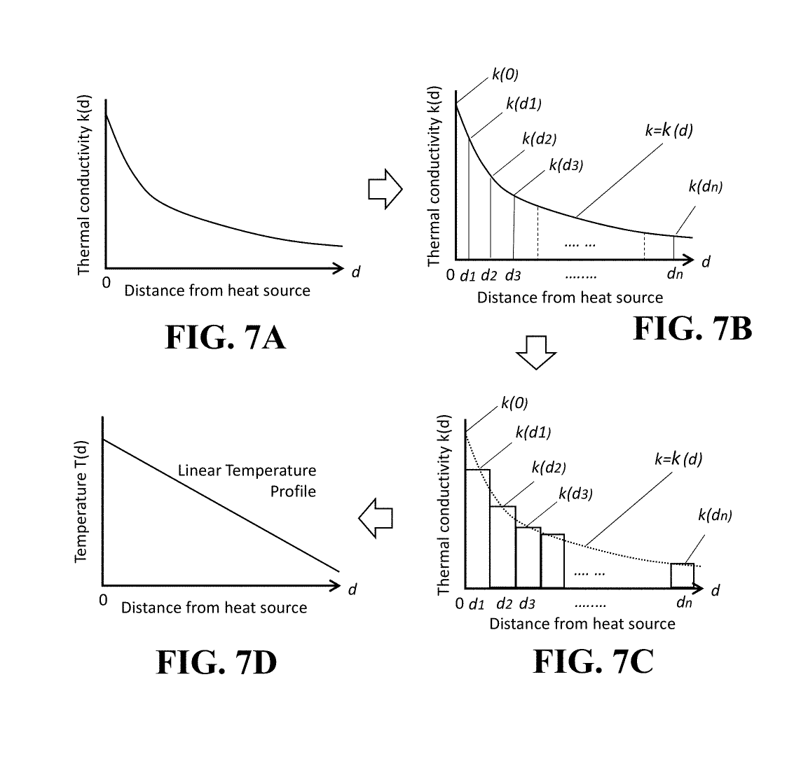

FIG. 7A, FIG. 7B, FIG. 7C and FIG. 7D show schematic designing process of a heat transfer device providing a liner temperature profile. After a shape of a heat transfer device and candidates for heat transfer materials are determined, a thermal conductivity profile as a function of distance from the heat source is obtained by solving a heat equation under the linear temperature profile requirement as shown in FIG. 7A. In this case, the shape of the heat transfer device, which connects between a heat source and a predetermined position with a temperature lower than that of the heat source, may be modelled by use of simple shape units such as cylinder, circular, ellipse, triangle, square, polygon, sphere or the like.

FIG. 7B shows that the thermal conductivity profile is discretized according to predetermined distances. For example, abrupt slope regions may be discretized with smaller distances than other gentle slope regions. Then each discretized position dₙ is assigned a thermal conductivity value k(dₙ).

FIG. 7C shows that a predetermined pair of material layers respectively having predetermined thicknesses is assigned to each discretized region so that an effective thermal conductivity k_{eff}(dₙ) of the material layers approximately corresponds to the thermal conductivity k(dₙ) as discussed above in FIG. 1C.

After determining each pair of layers for each discretized position, an approximately linear temperature profile across the material layers is obtained as shown in FIG. 7D. The procedure above may be iteratively performed until the linearity of obtained temperature profile reaches a predetermined range.

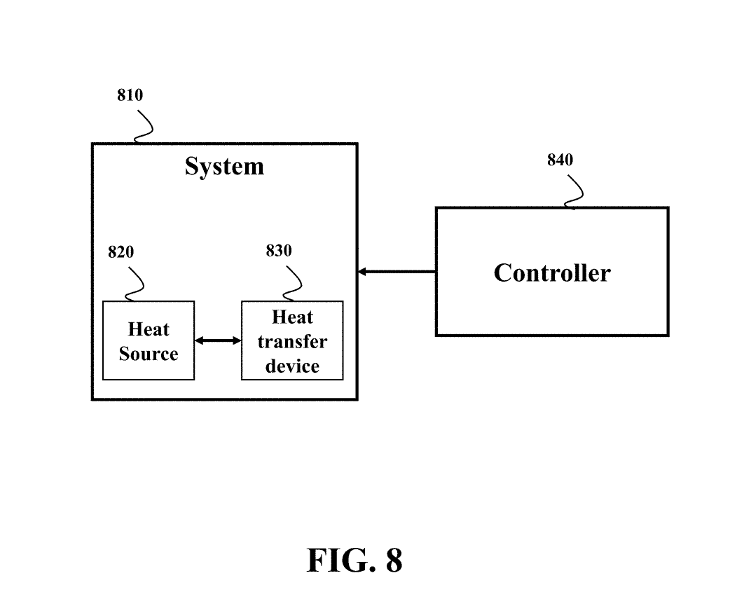

FIG. 8 shows a block diagram of a system 810 including a heat source 820 producing heat and the heat transfer device 830 for dissipating the heat from the heat source. The heat transfer device 830 employs principles of some embodiments and includes the layered structure where materials of the layers and thickness of the layers are selected such that the heat propagates through the layered structure of the heat transfer device according to a temperature profile approximating a function. The system includes a controller including a processor for controlling the system using a model of the system considering dissipation of the heat according to the function approximated by the heat transfer device. For example, the function is a linear function and the controller is a linear controller.

The above-described embodiments of the present invention can be implemented in any of numerous ways. For example, the embodiments may be implemented using hardware, software or a combination thereof. When implemented in software, the software code can be executed on any suitable processor or collection of processors, whether provided in a single computer or distributed among multiple computers. Such processors may be implemented as integrated circuits, with one or more processors in an integrated circuit component. Though, a processor may be implemented using circuitry in any suitable format.

Also, the various methods or processes outlined herein may be coded as software that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine. Typically, the functionality of the program modules may be combined or distributed as desired in various embodiments.

Also, the embodiments of the invention may be embodied as a method, of which an example has been provided. The acts performed as part of the method may be ordered in any suitable way. Accordingly, embodiments may be constructed in which acts are performed in an order different than illustrated, which may include performing some acts concurrently, even though shown as sequential acts in illustrative embodiments.

Although the invention has been described by way of examples of preferred embodiments, it is to be understood that various other adaptations and modifications can be made within the spirit and scope of the invention. Therefore, it is the object of the appended claims to cover all such variations and modifications as come within the true spirit and scope of the invention.

We claim:

1. A heat transfer device including a layered structure, comprising:
a first layer of a first material having a first thermal conductivity and a first thickness; and
a second layer of a second material having a second thermal conductivity and a second thickness, the second layer being connected to the first layer,
wherein the first thermal conductivity is different from the second thermal conductivity, and wherein the first thickness is different from the second thickness.

2. The heat transfer device of claim 1, wherein the first thermal conductivity, the second thermal conductivity, the first thickness, and the second thickness are selected such that the heat propagates through the layered structure of the heat transfer device according to a temperature profile expressed by a predetermined function.

3. The heat transfer device of claim 2, wherein the predetermined function is a linear function.

4. The heat transfer device of claim 2, wherein the temperature profile is formed by temperature propagation points of layers of the layered structure, and wherein the predetermined function fits the temperature propagation points such that the maximal error between the temperature propagation points and the predetermined function fitted into the temperature propagation points is below a threshold.

5. The heat transfer device of claim 1, wherein the layered structure includes layers of only the first and the second materials.

6. The heat transfer device of claim 1, wherein the layered structure includes alternating layers of the first and second materials, wherein thicknesses of layers of the first material in the alternating layers are decreasing as a function of a distance along a direction, and wherein thicknesses of layers of the second material in the alternating layers are increasing as a function of the distance along the direction.

7. The heat transfer device of claim 1, wherein the first layer is configured to contact a heat source and the first thermal conductivity is greater than the second thermal conductivity.

8. The heat transfer device of claim 7, wherein the heat transfer device is disposed to surround the heat source.

9. The heat transfer device of claim 1, wherein the heat transfer device has a cross section forming an ellipse.

10. The heat transfer device of claim 1, wherein the heat transfer device has a cross section forming a triangle.

11. The heat transfer device of claim 1, wherein the heat transfer device has a cross section forming a circle.

12. A system including a heat source producing heat and the heat transfer device of claim 2 for dissipating the heat from the heat source, further comprising:
a controller including a processor for controlling the system using a model of the system considering dissipation of the heat according to the predetermined function.

13. The system of claim 12, wherein the predetermined function is a linear function and the controller is a linear controller.
